(19) United States
(12) Patent Application Publication
(10) Pub. No.: US 2008/0157332 A1
(43) Pub. Date: Jul. 3, 2008

(54) Stacked semiconductor packages and methods of manufacturing stacked semiconductor packages

(75) Inventors: Cha-Jea Jo, Uiwang-si (KR); Seok-Ho Kim, Bucheon-si (KR); Ju-Il Choi, Suwon-si (KR); Chang-Woo Shin, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/000,384

(22) Filed: Dec. 12, 2007

(30) Foreign Application Priority Data
Dec. 29, 2006 (KR) 10-2006-0137912

(51) Int. Cl. H01L 23/538; H01L 21/58

(52) U.S. Cl. 257/686; 438/109; 257/E23.169; 257/E21.505

(57) ABSTRACT

A stacked semiconductor package may include: a substrate; semiconductor packages stacked on the substrate; an interconnection member formed on edges of the semiconductor packages; and a conductive reinforcement member formed on the interconnection member. Each of the semiconductor packages may include a conductive line. The interconnection member may electrically connect the conductive line of the semiconductor packages to the conductive line of at least one other semiconductor package. A method of manufacturing a stacked semiconductor package may include: forming semiconductor packages; stacking the semiconductor packages on a substrate; forming a mask pattern on the semiconductor packages and the substrate to expose the edges of the semiconductor packages; performing an electroless plating process on the edges of the semiconductor packages to form a seed layer; and performing an electroplating process on the seed layer to form an interconnection member for electrically connecting the conductive lines to each other.

### PRIORITY STATEMENT

This application claims priority from Korean Patent Application No. 10-2006-0137912, filed on Dec. 29, 2006, in the Korean Intellectual Property Office (KIPO), the entire contents of which are incorporated herein by reference.

### BACKGROUND

1. Field

Example embodiments relate to stacked semiconductor packages and methods of manufacturing the stacked semiconductor packages. Also, example embodiments relate to stacked semiconductor packages that include a plurality of stacked semiconductor chips and methods of manufacturing the stacked semiconductor packages.

2. Description of Related Art

Generally, various semiconductor processes may be carried out on a semiconductor substrate to form a plurality of semiconductor chips. To mount the semiconductor chips on a motherboard, a packaging process may be performed on the semiconductor substrate to form a semiconductor package.

Further, to increase the storage capacity of the semiconductor package, a stacked semiconductor package including a plurality of stacked semiconductor chips has been widely researched. Particularly, to stack wafer level packages formed by a wafer-level packaging process, diverse manners for electrically connecting edges of the stacked semiconductor chip have been proposed. Examples of conventional stacked semiconductor packages having the above-mentioned structure are disclosed in Japanese Patent Laid-Open Publication Nos. 2001-0250906 A and 2001-0210782 A, Korean Patent Laid-Open Publication No. 2003-0067501 A, etc.

However, in the conventional stacked semiconductor packages, interconnection layers for electrically connecting the edges of the semiconductor chips to each other may be formed by a complicated and expensive photolithography process. Further, to form the interconnection layers, a grinding process may be carried out to partially remove the edges of the stacked semiconductor chips.

Particularly, since the conventional interconnection layers may be exposed to the outside, the conventional interconnection layers may be easily damaged due to high heat and/or impacts applied from the outside.

Moreover, only two semiconductor chips may be stacked in the conventional stacked semiconductor package having different structures. Therefore, since three or more semiconductor chips may not be stacked, there may be a limitation in the increase of the storage capacity of the conventional stacked semiconductor package.

### SUMMARY

Example embodiments may provide stacked semiconductor packages that have at least two semiconductor chips readily stacked by a simple process. The semiconductor packages may have high durability with respect to an external impact and/or high heat.

Example embodiments also may provide methods of manufacturing the stacked semiconductor packages.

According to example embodiments, a stacked semiconductor package may include: a substrate; a plurality of semiconductor packages stacked on the substrate; an interconnection member formed on edges of the semiconductor packages; and/or a conductive reinforcement member formed on the interconnection member. Each of the semiconductor packages includes a conductive line that is exposed through an edge of the respective semiconductor package. The interconnection member electrically connects the conductive line of each of the semiconductor packages to the conductive line of at least one other of the semiconductor packages. The conductive reinforcement member reinforces electrical bonding strength between the conductive lines and the interconnection member.

According to example embodiments, a method of manufacturing a stacked semiconductor package may include: forming a plurality of semiconductor packages that have conductive lines exposed through edges of the semiconductor packages; stacking the semiconductor packages on a substrate; forming a mask pattern on the semiconductor packages and the substrate to expose the edges of the semiconductor packages; performing an electroless plating process on the edges of the semiconductor packages exposed through the mask pattern to form a seed layer on the semiconductor packages; and performing an electroplating process on the seed layer to form an interconnection member adapted to electrically connect the conductive lines to each other.

### BRIEF DESCRIPTION OF THE DRAWINGS

The above and/or other aspects and advantages will become more apparent and more readily appreciated from the following detailed description of example embodiments taken in conjunction with the accompanying drawings, in which:

FIG. 1 is a cross-sectional view illustrating a stacked semiconductor package according to example embodiments;

FIG. 2 is an enlarged cross-sectional view illustrating a semiconductor package of the stacked semiconductor package of FIG. 1;

FIG. 3 is a cross-sectional view illustrating the semiconductor package of FIG. 2 from which a bottom portion of the semiconductor package is removed;

FIG. 4 is a cross-sectional view illustrating the semiconductor packages of FIG. 3, on a tape, that are individually cut;

FIG. 5 is a cross-sectional view illustrating an insulation layer on the semiconductor packages of FIG. 4;

FIG. 6 is a cross-sectional view illustrating an adhesive on the semiconductor packages of FIG. 5;

FIG. 7 is a cross-sectional view illustrating the semiconductor packages of FIG. 6 stacked on a substrate;

FIG. 8 is a cross-sectional view illustrating a photoresist film on the stacked semiconductor packages of FIG. 7;

FIGS. 9A and 9B are a cross-sectional view and a plan view illustrating a photoresist pattern formed from the photoresist film of FIG. 8;

FIGS. 10A and 10B are a cross-sectional view and a plan view illustrating a first connection layer on edges of the stacked semiconductor packages;

FIGS. 11A and 11B are a cross-sectional view and a plan view illustrating a second connection layer growing from the first connection layer of FIGS. 10A and 10B;

FIGS. 12A and 12B are a cross-sectional view and a plan view illustrating a conductive reinforcement member on the second connection layer of FIGS. 11A and 11B;

FIG. 13 is a cross-sectional view illustrating the stacked semiconductor packages from which the photoresist pattern is removed;

FIG. 14 is a cross-sectional view illustrating a land on the substrate;

FIG. 15 is a cross-sectional view illustrating a protection layer on the conductive reinforcement member; and

FIG. 16 is a cross-sectional view illustrating a stacked semiconductor package according to example embodiments.

### DESCRIPTION OF EXAMPLE EMBODIMENTS

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” another component, it may be directly on, connected to, electrically connected to, or coupled to the other component or intervening components may be present. In contrast, when an element is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

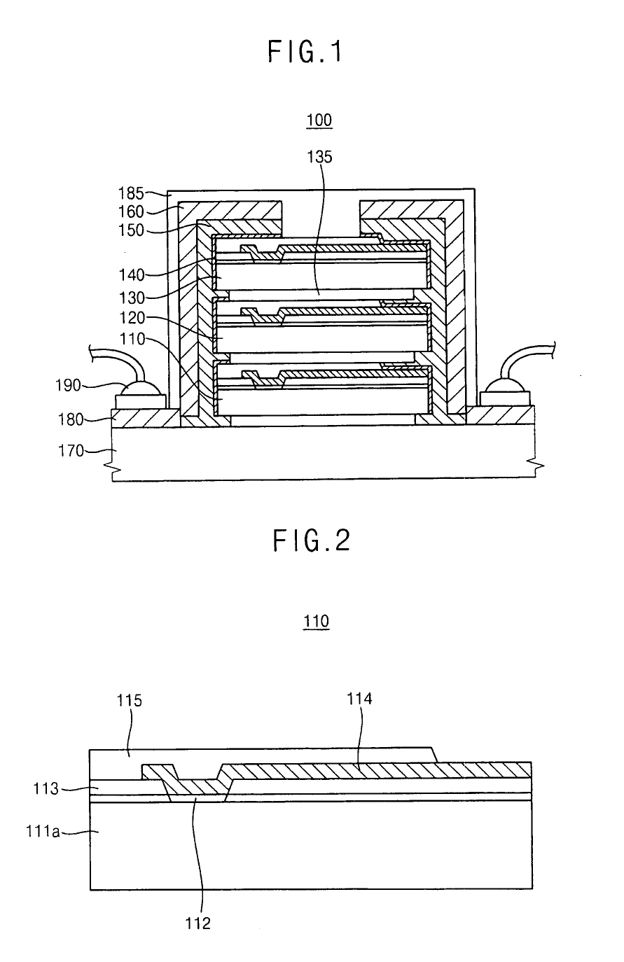

FIG. 1 is a cross-sectional view illustrating stacked semiconductor package 100 according to example embodiments, and FIG. 2 is an enlarged cross-sectional view illustrating semiconductor package 110 of stacked semiconductor package 100 of FIG. 1.

Referring to FIG. 1, a stacked semiconductor package 100 according to example embodiments may include a substrate 170, a first semiconductor package 110, a second semiconductor package 120, a third semiconductor package 130, an insulation layer 140, interconnection member 150, a conductive reinforcement member 160, lands 180, and/or outer terminals 190.

The substrate 170 may include a semiconductor substrate, such as a wafer. Further, the substrate 170 may have a thickness greater than or equal to about 20 μm and less than or equal to about 50 μm. For example, the substrate 170 may have a thickness of about 30 μm.

The first semiconductor package 110, the second semiconductor package 120, and/or the third semiconductor package 130 may be sequentially stacked on the substrate 170. Adhesives 135 may be interposed between the first semiconductor package 110 and the second semiconductor package 120, and/or between the second semiconductor package 120 and the third semiconductor package 130. In FIG. 1, for example, three semiconductor packages are illustrated. However, the number of semiconductor packages may be two, three, four, five, six, seven, eight, nine, ten, or more.

Detailed configurations of the first semiconductor package 110, the second semiconductor package 120, and/or the third semiconductor package 130 are depicted in FIG. 2. For example, the first semiconductor package 110, the second semiconductor package 120, and/or the third semiconductor package 130 may have a substantially similar structure. According to example embodiments, only the structure of the first semiconductor package 110 is illustrated.

Referring to FIG. 2, the first semiconductor package 110 may correspond to a wafer level package including a semiconductor chip 111a, a first insulation layer pattern 113, a conductive line 114, and/or a second insulation layer pattern 115. A pad 112 may be formed on a surface of the semiconductor chip 111a. The first insulation layer pattern 113 may be formed on the semiconductor chip 111a. The first insulation layer pattern 113 may have an opening for exposing the pad 112. The conductive line 114 may be formed on the first insulation layer pattern 113. The conductive line 114 may have a first end electrically connected to the pad 112 and/or a second end extending from the first end to an edge of the semiconductor chip 111a. The second insulation layer pattern 115 may be formed on the conductive line 114 to expose the second end of the conductive line 114. Thus, the second end of the conductive line 114 may be exposed through the edge of the first semiconductor package 110. For example, an upper face and a side face of the second end may be exposed through the edge of the first semiconductor package 110.

Referring again to FIG. 1, the insulation layer 140 may be formed on the edges of the first semiconductor package 110, the second semiconductor package 120, and/or the third semiconductor package 130. The insulation layer 140 may have openings for exposing the second ends of the conductive lines 114 in the first semiconductor package 110, the second semiconductor package 120, and/or the third semiconductor package 130. The insulation layer 140 may prevent an electrical short circuit between the first semiconductor package 110, the second semiconductor package 120, and/or the third semiconductor package 130. According to example embodiments, an example of the insulation layer 140 may include a low temperature insulation layer, such as a silicon nitride layer.

The interconnection member 150 may be formed on the second end of the conductive line 114 and/or the insulation layer 140. According to example embodiments, the interconnection member 150 may be formed by an electroless plating process on the second end of the conductive line 114 and/or the insulation layer 140 to form a seed layer (not shown), and by an electroplating process on the seed layer. Further, the interconnection member 150 may have a structure protruded from the edges of the first semiconductor package 110, the second semiconductor package 120, and/or the third semiconductor package 130. Examples of the interconnection member 150 include copper, nickel, silver, alloys of those metals (alone or in combination), etc.

The conductive reinforcement member 160 may be formed on the interconnection member 150. The conductive reinforcement member 160 may reinforce an electrical bonding strength between the interconnection member 150 and the conductive line 114. Further, the conductive reinforcement member 160 may have a relatively strong mechanical strength to protect the interconnection member 150 from external impacts. Furthermore, the conductive reinforcement member 160 may function to absorb excessive heat from the first semiconductor package 110, the second semiconductor package 120, and/or the third semiconductor package 130, and/or thermal expansion differences between the first semiconductor package 110, the second semiconductor package 120, and/or the third semiconductor package 130. According to example embodiments, an example of the conductive reinforcement member 160 having one or more of the above-mentioned functions may include an invar alloy. The invar alloy may include, for example, iron and nickel. For example, the invar alloy may have a thermal expansion coefficient of about 0 ppm.

Additionally, the protection layer 185 may be formed on the conductive reinforcement member 160. The protection layer 185 also may function to electrically insulate the conductive reinforcement member 160.

The lands 180 may be formed on the substrate 170. Further, the lands 180 may be electrically connected to the conductive reinforcement member 160. The outer terminals 190 may be mounted on the lands 180. According to example embodiments, the outer terminals 190 may include one or more conductive wires.

According to example embodiments, the conductive reinforcement member 160, possibly including the invar alloy, may support the interconnection member 150 for electrically connecting the conductive lines 114 to each other. Thus, the electrical bonding strength between the interconnection member 150 and the conductive lines 114 may be reinforced. As a result, the electrical contact between the interconnection member 150 and the conductive lines 114 may have improved reliability.

Hereinafter, a method of manufacturing the stacked semiconductor package 100 in FIG. 1 is illustrated in detail with reference to FIGS. 2 to 15.

Referring to FIG. 2, a packaging process may be carried out on a wafer that includes a plurality of semiconductor chips 111a to form the first semiconductor package 110. According to example embodiments, a first insulation layer (not shown) may be formed on the semiconductor chip 111a. The first insulation layer may be patterned to form a first insulation layer pattern 113 that may have an opening that exposes the pad 112. A conductive layer (not shown) may be formed on the first insulation layer pattern 113 to fill up the opening with the conductive layer. The conductive layer may then be patterned to form the conductive line 114 having the first end and the second end. For example, the first end may be electrically connected to the pad 112. The second end may extend to the edge of the semiconductor chip 111a. A second insulation layer (not shown) may be formed on the first insulation layer pattern 113 and/or the conductive line 114. The second insulation layer may then be patterned to form a second insulation layer pattern 115 that may have an opening that exposes the second end of the conductive line 114.

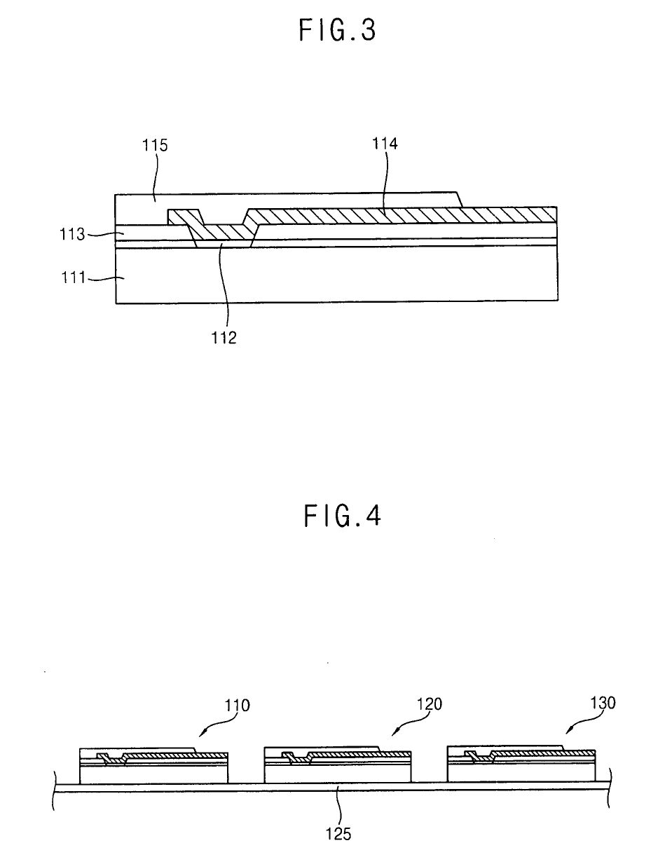

Referring to FIG. 3, to reduce the thickness of the stacked semiconductor package 100, a bottom face of the semiconductor chip 111a may be partially removed by a grinding process. For example, a thickness of the wafer 111, i.e., the ground semiconductor chip 111a, may be greater than or equal to about 20 μm and less than or equal to about 50 μm. For example, the thickness of the wafer 111 may be about 30 μm.

Referring to FIG. 4, the wafer 111 may then be attached to a tape 125. The wafer 111 may be cut along a scribe lane (not shown) to divide the wafer 111 into separated semiconductor packages, i.e., the first semiconductor package 110, the second semiconductor package 120, and/or the third semiconductor package 130. The tape 125 may then be elongated to widen the intervals between the separated semiconductor packages.

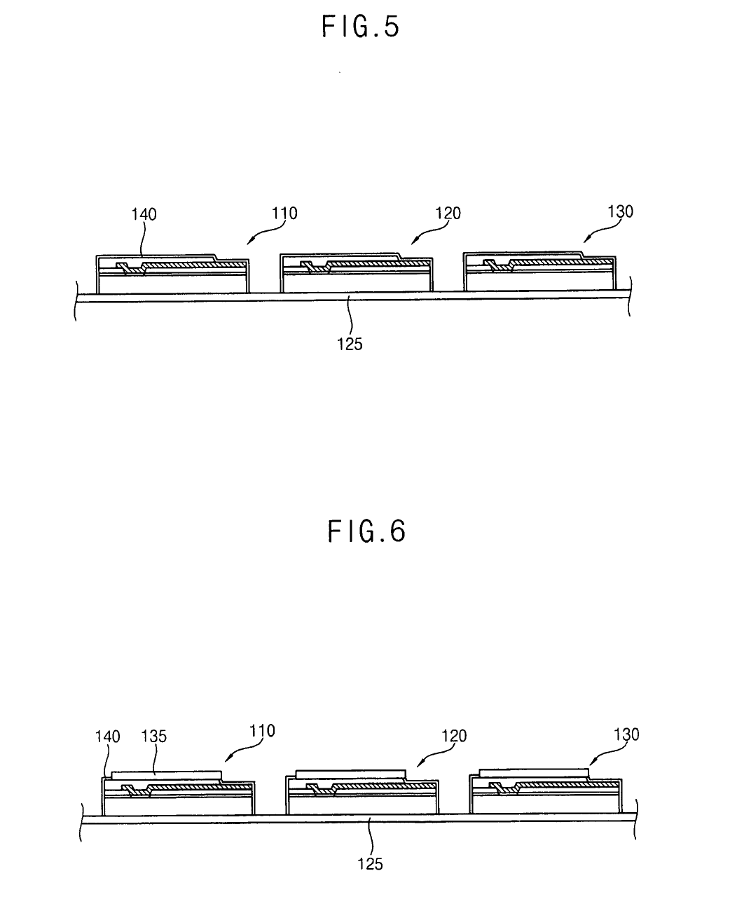

Referring to FIG. 5, the insulation layer 140 may be formed on the first semiconductor package 110, the second semiconductor package 120, and/or the third semiconductor package 130. For example, the insulation layer 140 may prevent an electrical short circuit between the first semiconductor package 110, the second semiconductor package 120, and/or the third semiconductor package 130 when they may be stacked later. To prevent the conductive line 114 from being covered with the insulation layer 140, the insulation layer 140 may have an opening (not shown) for exposing the conductive line 114. According to example embodiments, the insulation layer 140 may be formed, for example, by a plasma-enhanced chemical vapor deposition (PECVD) process using, for example, silicon nitride.

The insulation layer 140 may be formed, for example, on all or part of the first semiconductor package 110, the second semiconductor package 120, and/or the third semiconductor package 130. In the alternative, the insulation layer 140 may be formed, for example, on all of the first semiconductor package 110, the second semiconductor package 120, and/or the third semiconductor package 130, and then removed from part of the first semiconductor package 110, the second semiconductor package 120, and/or the third semiconductor package 130.

Referring to FIG. 6, the adhesive 135 may then be formed on the first semiconductor package 110, the second semiconductor package 120, and/or the third semiconductor package 130. The adhesive 135 may include a material for attaching the wafer 111 of a lower semiconductor package to the second insulation layer pattern 115 of an upper semiconductor package.

The adhesive 135 may be formed, for example, on the first semiconductor package 110 and the second semiconductor package 120, but not on the third semiconductor package 130. The adhesive 135 may not be formed on the third semiconductor package 130, for example, when the insulation layer 140 is formed on all of the third semiconductor package 130.

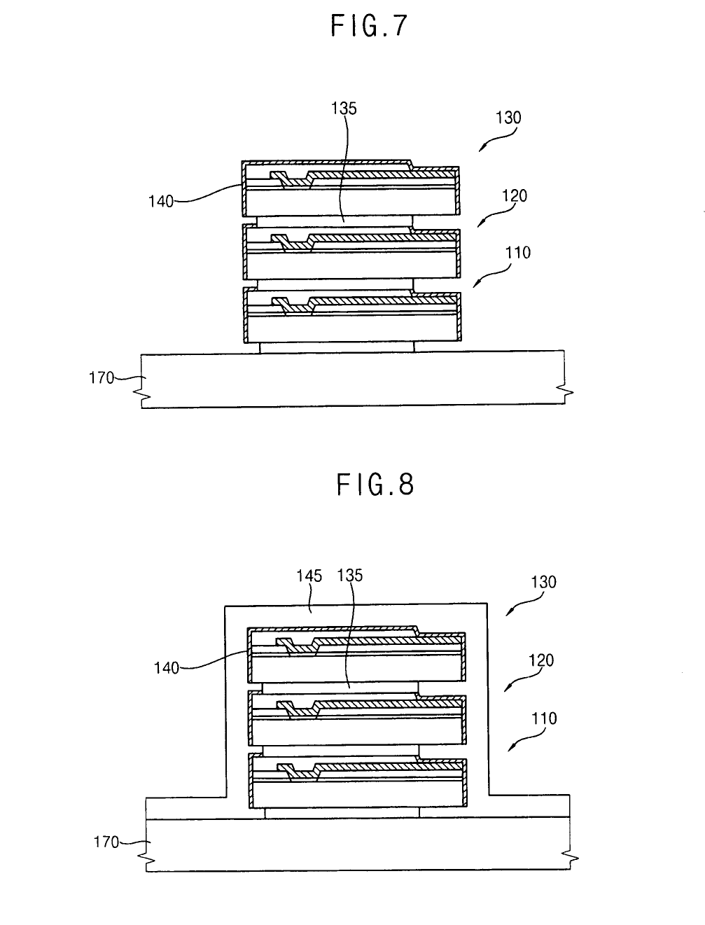

Referring to FIG. 7, the adhesive 135 may also be formed on the substrate 170. The first semiconductor package 110, the second semiconductor package 120, and/or the third semiconductor package 130 may be sequentially stacked on the substrate 170, using the adhesive 135. The conductive lines 114 of stacked the first semiconductor package 110, the second semiconductor package 120, and/or the third semiconductor package 130 may be exposed through the edges of the first semiconductor package 110, the second semiconductor package 120, and/or the third semiconductor package 130.

Referring to FIG. 8, a masking film, such as a photoresist film 145, may then be formed on the substrate 170 and/or the stacked first semiconductor package 110, second semiconductor package 120, and/or third semiconductor package 130. Thus, the stacked first semiconductor package 110, second semiconductor package 120, and/or third semiconductor package 130 may be covered with the photoresist film 145. The insulation layer 140 may be removed from part of the third semiconductor package 130, for example, prior to forming the photoresist film 145.

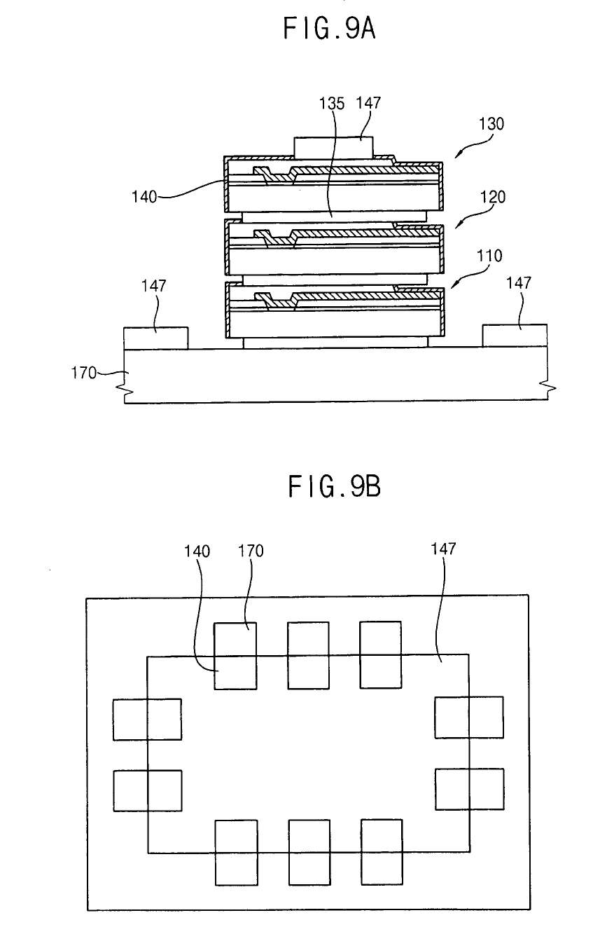

Referring to FIGS. 9A and 9B, the photoresist film 145 may be exposed and developed to form a photoresist pattern 147, exposing the edges of the stacked first semiconductor package 110, second semiconductor package 120, and/or third semiconductor package 130. Therefore, the conductive lines 114 may be exposed through the photoresist pattern 147.

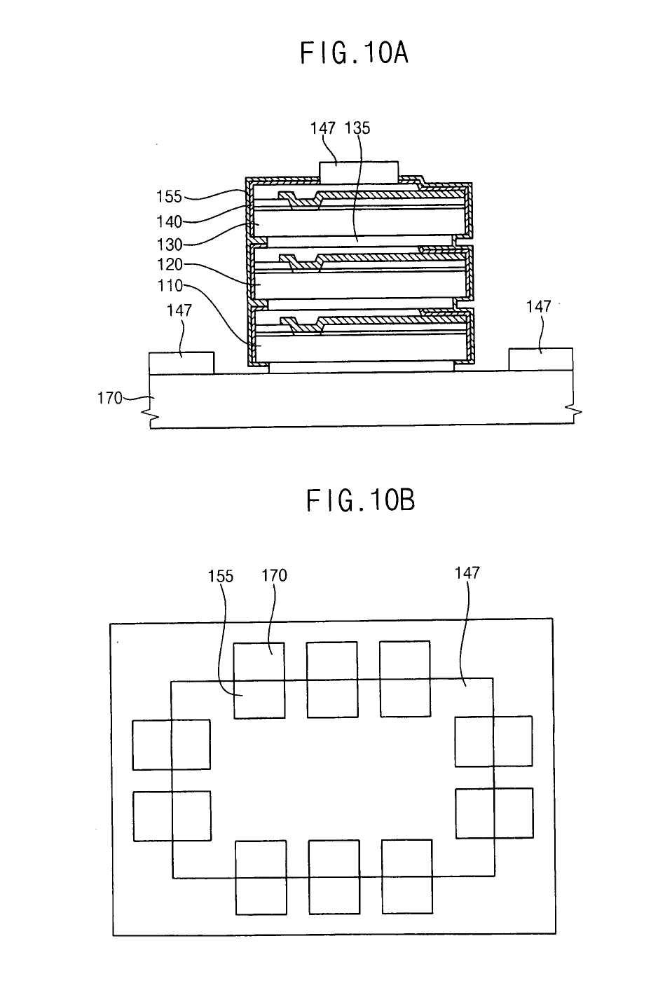

Referring to FIGS. 10A and 10B, an electroless plating process may then be carried out on the conductive lines 114 and/or the insulation layer 140 exposed through the photoresist pattern 147 to form a seed layer 155 on the conductive line 114 and/or the insulation layer 140. Thus, the conductive lines 114 of the first semiconductor package 110, the second semiconductor package 120, and/or the third semiconductor package 130 may be electrically coupled to each other through the seed layer 155. According to example embodiments, plating solutions that may be used for the electroless plating process may include a copper solution, a nickel solution, a silver solution, a solution of alloys of those metals (alone or in combination), etc. As a result, the seed layer 155 may include a copper layer, a nickel layer, a silver layer, a layer of alloys of those metals (alone or in combination), etc.

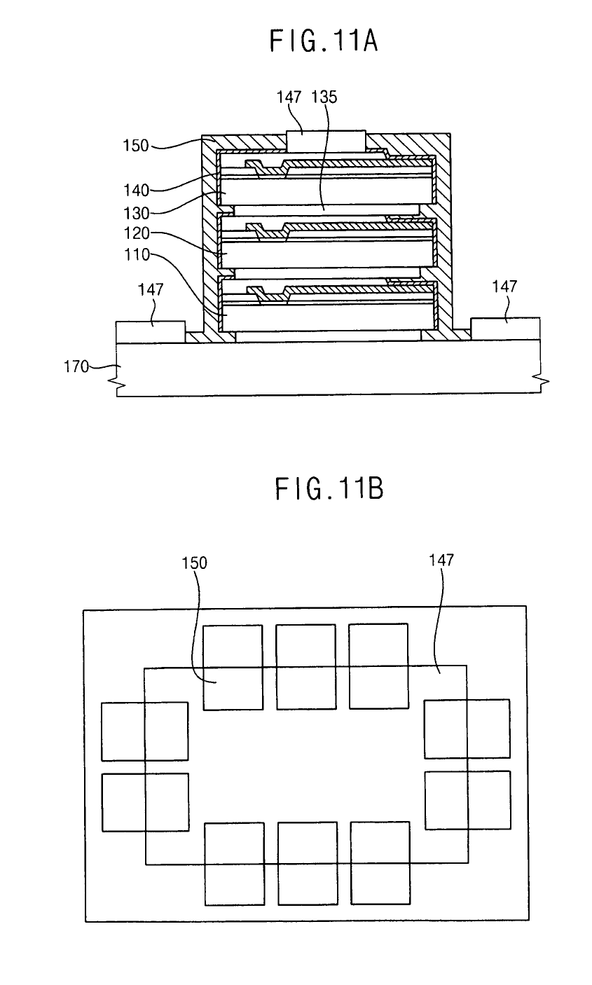

Referring to FIGS. 11A and 11B, an electroplating process may then be carried out on the seed layer 155 to grow the interconnection member 150 from the seed layer 155. According to example embodiments, the interconnection member 150 may have edges protruded from the edges of the first semiconductor package 110, the second semiconductor package 120, and/or the third semiconductor package 130. For example, since the interconnection member 150 may include a material substantially similar to that of the seed layer 155, the interconnection member 150 may include a copper layer, a nickel layer, a silver layer, a layer of alloys of those metals (alone or in combination), etc.

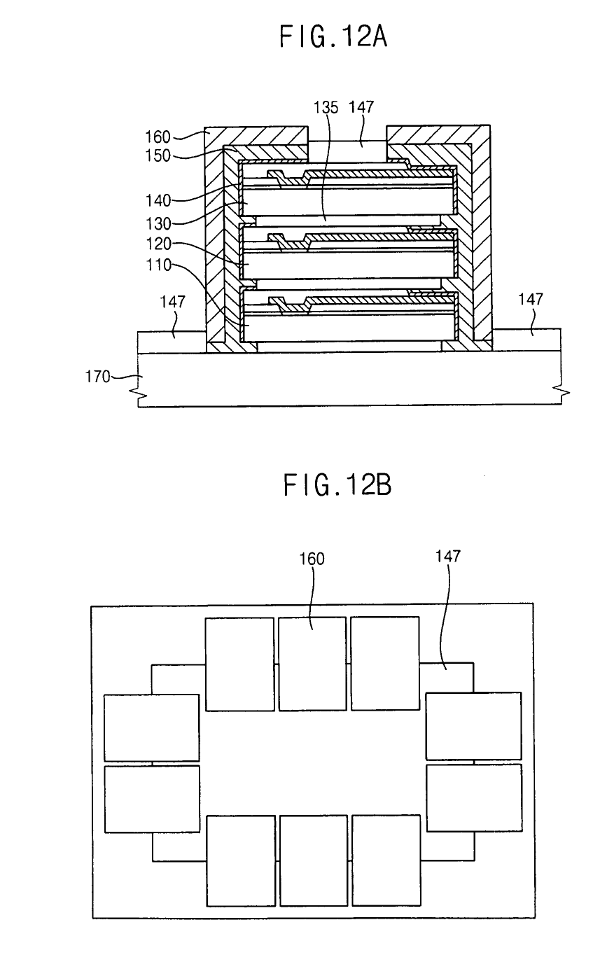

Referring to FIGS. 12A and 12B, the conductive reinforcement member 160 may then be formed on the interconnection member 150. For example, the conductive reinforcement member 160 may reinforce an electrical bonding strength between the interconnection member 150 and the conductive line 114. Further, the conductive reinforcement member 160 may have a strong mechanical strength for protecting the interconnection member 150 from external impacts. Furthermore, since the conductive reinforcement member 160 may have a thermal expansion coefficient of about 0 ppm, the conductive reinforcement member 160 may offset overheating of the first semiconductor package 110, the second semiconductor package 120, and/or the third semiconductor package 130 by a thermal expansion difference between the first semiconductor package 110, the second semiconductor package 120, and/or the third semiconductor package 130. According to example embodiments, the conductive reinforcement member 160 may include, for example, an invar alloy. The invar alloy may include, for example, iron and nickel. The invar alloy may be formed, for example, by performing an electroplating process on the interconnection member 150.

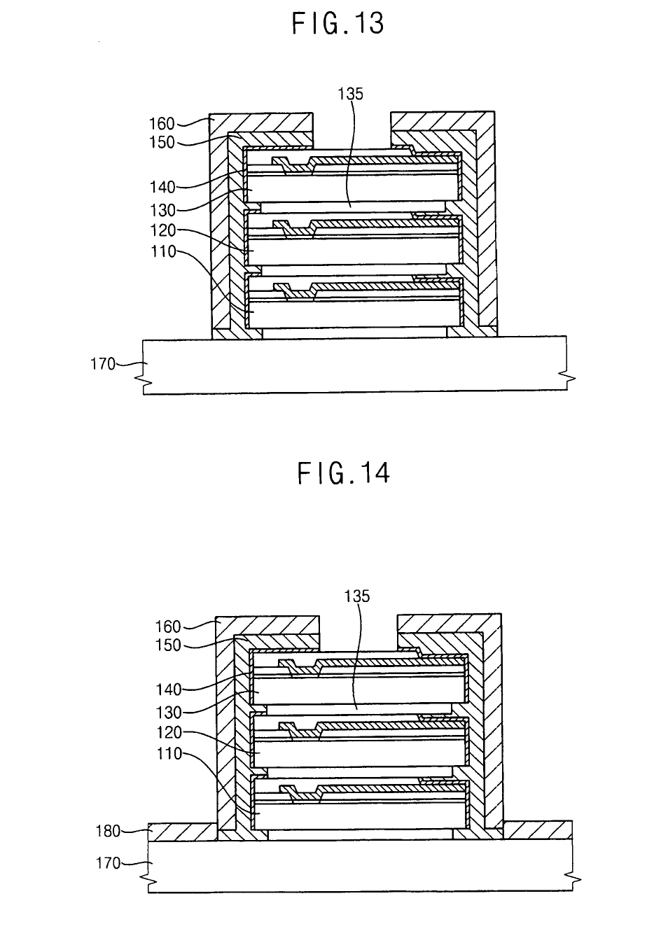

Referring to FIG. 13, the photoresist pattern 147 remaining on the third semiconductor package 130 and/or the substrate 170 may then be removed. According to example embodiments, the photoresist pattern 147 may be removed by an etching process and/or a stripping process.

Referring to FIG. 14, the lands 180 may be formed on the substrate 170. The lands 180 may be electrically connected to the conductive reinforcement member 160. For example, the lands 180 may be formed simultaneously with the formation of the conductive reinforcement member 160. That is, the electroplating process may be carried out on the interconnection member 150 to simultaneously form the conductive reinforcement member 160 and the lands 180.

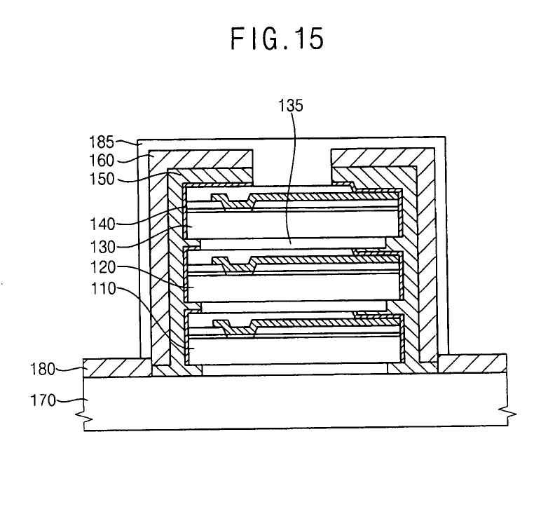

Referring to FIG. 15, the protection layer 185 may be formed on the conductive reinforcement member 160. According to example embodiments, the protection layer 185 may include an insulation layer, such as an oxide layer having an insulation characteristic.

Referring again to FIG. 1, the outer terminals 190 (and/or conductive wires) may then be formed on the lands 180 to complete the stacked semiconductor package 100.

According to example embodiments, the interconnection member 150 may be readily formed by the electroless plating process and/or the electroplating process at a low expense. Thus, the process for forming the stacked semiconductor package 100 may become simple.

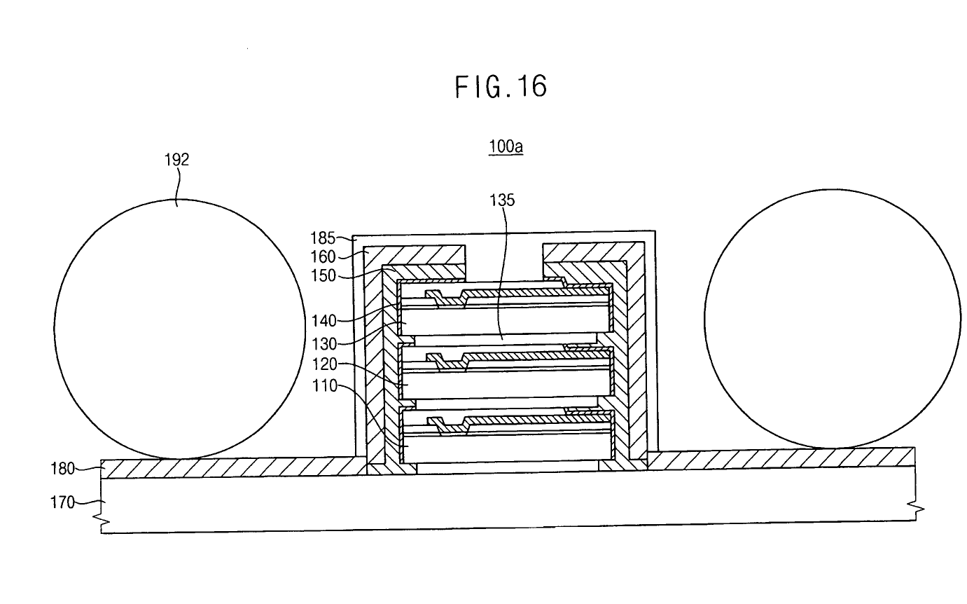

FIG. 16 is a cross-sectional view illustrating a stacked semiconductor package 100a according to example embodiments.

The stacked semiconductor package 100a according to example embodiments may include elements substantially similar to those of the stacked semiconductor package 100, except for outer terminals 190. Thus, the same reference numerals refer to the same elements and any further illustrations with respect to the same elements are omitted herein for brevity.

Referring to FIG. 16, the stacked semiconductor package 100a according to example embodiments may include solder balls 192 as outer terminals. For example, since the solder balls 192 may have a size allowing the solder balls 192 to be mounted on a motherboard, the solder balls 192 may have a diameter larger than the thickness from the substrate 170 to the protection layer 185.

A method of manufacturing the stacked semiconductor package 100a having the above-mentioned structure may be substantially the same as that discussed above, except for mounting the solder balls 192 on the lands 180, in place of the outer terminals 190. Therefore, any further illustrations with respect to the method of manufacturing the stacked semiconductor package 100a are omitted herein for brevity.

According to example embodiments, the interconnection member 150 may be readily formed by the simple electroless plating process and/or the simple electroplating process. Thus, the stacked semiconductor package 100a may be manufactured by a simple process at a low expense.

Further, the conductive reinforcement member 160 may improve the electrical contact reliability between the interconnection member 150 and the conductive line 114. Furthermore, since the conductive reinforcement member 160 may surround the interconnection member 150, the interconnection member 150 may not be damaged due to external impact and/or high heat.

While example embodiments have been particularly shown and described, it will be understood by those of ordinary skill in the art that various changes in form and details may be made therein without departing from the spirit and scope of the present invention as defined by the following claims.

What is claimed is:

1. A stacked semiconductor package, comprising:
a substrate;
a plurality of semiconductor packages stacked on the substrate;
an interconnection member formed on edges of the semiconductor packages; and
a conductive reinforcement member formed on the interconnection member;
wherein each of the semiconductor packages includes a conductive line that is exposed through an edge of the respective semiconductor package,
wherein the interconnection member electrically connects the conductive line of each of the semiconductor packages to the conductive line of at least one other of the semiconductor packages, and
wherein the conductive reinforcement member reinforces electrical bonding strength between the conductive lines and the interconnection member.

2. The stacked semiconductor package of claim 1, wherein each of the semiconductor packages comprises:
a semiconductor chip;
a pad;
a first insulation layer pattern formed on the semiconductor chip to expose the pad;
the conductive line; and
a second insulation layer pattern formed on the conductive line;
wherein the conductive line includes a first end and a second end,
wherein the first end is electrically connected to the pad,
wherein the second end extends along a surface of the first insulation layer pattern,
wherein the second end is exposed through an edge of the semiconductor chip, and
wherein the second insulation layer pattern exposes the second end of the conductive line.

3. The stacked semiconductor package of claim 1, wherein the interconnection member includes a protruded portion from side faces of the semiconductor packages.

4. The stacked semiconductor package of claim 1, wherein the interconnection member comprises one or more of copper, nickel, and silver.

5. The stacked semiconductor package of claim 1, wherein the conductive reinforcement member comprises an invar alloy that includes iron and nickel.

6. The stacked semiconductor package of claim 1, further comprising:
an insulation layer interposed between the edges of the semiconductor packages and the interconnection member;
wherein the insulation layer partially exposes the conductive lines.

7. The stacked semiconductor package of claim 6, wherein the insulation layer comprises a silicon nitride layer.

8. The stacked semiconductor package of claim 1, further comprising:
a land formed on the substrate; and
an outer terminal formed on the land;
wherein the land is electrically connected to the conductive reinforcement member.

9. The stacked semiconductor package of claim 8, wherein the outer terminal comprises a conductive wire or a solder ball.

10. A method of manufacturing a stacked semiconductor package, comprising:
forming a plurality of semiconductor packages that have conductive lines exposed through edges of the semiconductor packages;
stacking the semiconductor packages on a substrate;
forming a mask pattern on the semiconductor packages and the substrate to expose the edges of the semiconductor packages;
performing an electroless plating process on the edges of the semiconductor packages exposed through the mask pattern to form a seed layer on the semiconductor packages; and
performing an electroplating process on the seed layer to form an interconnection member adapted to electrically connect the conductive lines to each other.

11. The method of claim 10, wherein forming the plurality of semiconductor packages comprises:
forming a first insulation layer pattern on a semiconductor chip, including a pad, to expose the pad;
extending the conductive line from the pad along a surface of the first insulation layer pattern; and
forming a second insulation layer pattern on the conductive line to expose an end of the conductive line.

12. The method of claim 11, further comprising:
partially removing a bottom portion of the semiconductor chip.

13. The method of claim 10, further comprising:
forming an insulation layer on the semiconductor packages to partially expose the conductive lines.

14. The method of claim 10, wherein stacking the semiconductor packages comprises forming an adhesive that acts on the semiconductor packages.

15. The method of claim 10, wherein the mask pattern comprises a photoresist pattern.

16. The method of claim 10, further comprising:
forming a conductive reinforcement member on the interconnection member;
wherein the conductive reinforcement member reinforces electrical bonding strength between the conductive lines and the interconnection member.

17. The method of claim 16, wherein the conductive reinforcement member is formed by a plating process with respect to the interconnection member.

18. The method of claim 16, wherein the conductive reinforcement member comprises an invar alloy that includes iron and nickel.

19. The method of claim 10, further comprising:
forming a land on the substrate; and
forming an outer terminal on the land.
